(19) United States
(12) Patent Application Publication
(10) Pub. No.: US 2025/0058639 A1
(43) Pub. Date: Feb. 20, 2025

(54) METHOD FOR DETECTING A LOSS OF GROUND CONNECTION, CONTROLLER, AND BRAKE SYSTEM

(71) Applicant: Continental Automotive Technologies GmbH, Hannover (DE)

(72) Inventor: Patric Schäfer, Grolsheim (DE)

(73) Assignee: Continental Automotive Technologies GmbH, Hannover (DE)

(21) Appl. No.: 18/722,193

(22) PCT Filed: Dec. 15, 2022
(86) PCT No.: PCT/DE2022/200299

§ 371 Date: Jun. 20, 2024

(30) Foreign Application Priority Data
Dec. 22, 2021 (DE) 10 2021 214 955.3

(51) Int. Cl. B60L 3/00

(52) U.S. Cl. CPC B60L 3/0069; B60L 3/0076; B60L 3/0084

(57) ABSTRACT

A brake system, a controller and a method for detecting a loss of ground connection in a controller for a vehicle are disclosed. The controller has a first unit and a second unit, and the first and/or the second unit comprise(s) a microcontroller. The first unit is connected to a first ground terminal by a first ground line and the second unit is connected to a second ground terminal by a second ground line. The controller comprises a single ground loss detection resistor arranged in the first or in the second ground line. The current in the first and/or the second ground line is ascertained and evaluated by the microcontroller in order to determine whether a loss of the connection has occurred at one of the ground terminals.

### TECHNICAL FIELD

A method for detecting a loss of ground connection to a controller for a vehicle and to a brake system for a vehicle is disclosed.

### BACKGROUND

Previous circuits for ground loss detection (GLD), especially in controllers for brake systems in vehicles, use two resistors to measure currents, in particular operating currents. One of the resistors is arranged here in each ground line in order to detect a malfunction in the redundant ground line connection between the controller and the vehicle body. Such a circuit is described, for example, in document DE 11 2016 002 693 T5.

FIG. 1 shows an equivalent circuit diagram of the double or redundant ground connection with one mesh and two nodes. The calculation of the mesh is independent of the number of printed circuit boards used. Previous controllers use two printed circuit boards—one for the actuator and one for the modulator. The two ground surfaces on the respective printed circuit boards are connected via a cross connection. This cross connection is represented by the resistor Rcc.

The current Ip in this case stands for the current that flows from the actuator to the left-hand node. Ivs represents the current that flows from the modulator to the right-hand node. The two currents I1 and I2 in this case represent the currents that in each case flow out in the direction of the vehicle body via the series circuit composed of shunt, contact system and ground line. For the sake of clarity, the three individual resistors are grouped together in the resistors R1 and R2.

The shunt (resistor) for measuring the current has the smallest proportion of the total resistance. In the event of a ground interruption, the contribution of the line resistance to the total resistance prevails. It is infinitely large and no more current can flow via this ground path.

The ground interruption is detected based on the zero current in the respective ground line to the vehicle body. The current, which in the fault-free state flows off in the direction of the vehicle body via a ground line, causes a voltage drop across the shunt which is connected in series, said voltage drop being made available to the microcontroller for evaluation in an amplified and digitally converted form. The voltage drop is then recalculated back into a current by the software. If this current is then measured at zero, all of the current consequently flows to the vehicle body via the second ground path.

If the ground, especially the ground line of the actuator, is interrupted, the resistor R2 comes to have a high resistance (infinitely large). I2 is therefore zero. The current Ip, which flows to the left-hand node, must therefore flow via Rcc in the direction of the right-hand node and from there flows via R1 in the direction of the vehicle body. This all also applies in reverse. If the ground of the modulator is interrupted, the resistor R1 comes to have a high resistance (infinitely large). The current Ivs flows from the right-hand node via the cross connection Rcc to the left-hand node and from there via R2 in the direction of the vehicle body. As long as there is a ground connection, at least the logic part on the actuator and modulator can be maintained in terms of function. This means that the actuator and modulator can detect the interruption of the associated ground line via the “zero” current measurement.

In order to successfully detect a ground loss, the two currents must be measured in synchronization during the application of a test pulse. To do this, the operating current must be divided between both ground lines. However, the individual components entail relatively high costs and take up space on the printed circuit board. Complex calculations in the software are also required for the evaluation process. Application-specific parameter adaptation is usually required.

Another circuit arrangement is described in document DE 198 36 734 A1 using the example of a method for testing the function of an ignition circuit of a passenger protection system. However, the proposed circuit arrangement only comprises one ground line; a second ground line acts as a reference to the first ground line. The second ground emulates a maximum resistance value using the substrate of the first ground line, which may occur so that the igniter can only just be triggered. In the event of a fault on the first ground line, the current is diverted to the auxiliary ground. The substrate resistance leads to an increase in potential, which can be evaluated by means of a comparator. A redundant ground connection is therefore not available, which may lead to the fact that, in the event of failure of the first ground line, for example, the functionality of the circuit arrangement can no longer be guaranteed.

### SUMMARY

It is therefore the object to improve the detection of a ground loss, in particular reducing costs and saving space on the printed circuit board.

The functionality of the circuit arrangement should be maintained as far as possible, even if a ground line fails.

Therefore a connected controller could continue to work, for example in the event of a failure of or defect in a ground line, such as the first ground line.

A method for detecting a loss of ground connection, in particular a loss of ground connection in a redundant ground connection comprising a controller for a vehicle is disclosed. The controller has a first unit and a second unit, and wherein the first unit and/or the second unit comprise(s) a microcontroller, and wherein the first unit is connected to a first ground terminal by means of a first ground line and the second unit is connected to a second ground terminal by means of a second ground line. The controller comprises a single ground loss detection resistor which is arranged in the first or in the second ground line. The following steps are carried out: ascertaining the current in the first and/or the second ground line and evaluating the measured current by way of the microcontroller to determine whether a loss of the connection has occurred at one of the ground terminals.

A single ground loss detection resistor means that there is only one. That is to say, no other ground loss detection resistor. The embodiment therefore requires only a single ground loss detection resistor (shunt) to identify a ground loss. This saves costs for the second shunt and frees up space on the printed circuit board for other components.

According to an embodiment, a first unit of a controller comprises a first printed circuit board, and the second unit comprises a second printed circuit board. A controller may therefore comprise a first unit having a first printed circuit board and a second unit having a second printed circuit board. The two printed circuit boards may therefore be structurally separate from one another, but this does not have to rule out the fact that the two printed circuit boards can be connected to one another by means of other components or electrical lines.

Both units can thus comprise two different printed circuit boards and can be associated here with a single controller. The first printed circuit board may be connected here to a first ground terminal by means of a first ground line and the second printed circuit board may be connected here to a second ground terminal by means of a second ground line. The controller may therefore have two external, physically separated ground lines to the vehicle body.

According to an embodiment, the first and second ground lines can be connected to one another via a cross connection (“interconnection”), which allows the currents to flow back, especially in the case of a ground interruption.

During operation of the controller, the operating current can thus be divided between both ground lines, which corresponds to the normal operating behavior. A test current, such as that required for instance in the circuit arrangement of DE 198 36 734 A1, is not necessary. In other words, the embodiments can be used to detect a ground interruption under normal operating conditions and using operating current alone. As soon as the first or the second ground line has a defect, for example tears, this defect can be detected in a manner according to the embodiments. Especially in the case of a ground interruption in the first ground line, there is no increase in potential here.

The embodiments offer a redundant ground connection. This allows the controller or the corresponding functions to be maintained even in the event of a failure of or defect in a ground line, such as the first ground line. This is not the case with the circuit arrangement of DE 198 36 734 A1, since the functions can no longer be enabled in the event of a defect in the main ground line.

In a development, the evaluating microcontroller and the ground loss detection resistor are arranged in the second unit, that is to say on the second printed circuit board to implement the evaluation process.

In a development, two current threshold values are defined and the current in the second ground line is measured, wherein a loss of the connection via the second ground line is identified by virtue of the fact that the current falls below the first current threshold value and a loss of the connection via the first ground line is identified by virtue of the fact that the current exceeds the second current threshold value.

As an alternative, the current in the first ground line is measured, wherein a loss of the connection via the first ground line is identified by virtue of the fact that the current falls below the first current threshold value and a loss of the connection via the second ground line is identified by virtue of the fact that the current exceeds the second current threshold value.

In a development, the level of the minimum required current for the evaluation is selected depending on the offset error of the analog-to-digital converter. For example, the minimum current is selected to be greater, the greater the offset error is. In a development, the resistance value of the ground loss detection resistor is corrected by the ambient temperature.

In a development, the nominal resistance of the ground loss detection resistor is corrected by the tolerances of the printed circuit board. By correcting and selecting the level of the minimum required current, a more accurate result is achieved in the evaluation of the signals and thus in the identification of a ground interruption.

In a development, the measured current is processed as a root mean square value. The root mean square value may also be referred to here as the “true RMS variable”. The development makes it possible to process the useful signal with maximum quantity. In addition, there is no need to implement further software algorithms for hiding purposes for certain control functions (for example ABS).

The object is also achieved by way of a controller for a vehicle, wherein the controller has a first unit and a second unit and wherein the first unit and/or the second unit comprise(s) a microcontroller and wherein the first unit is connected to a ground terminal by means of a first ground line and the second unit is connected to the ground terminal by means of a second ground line and wherein the controller comprises a single ground loss detection resistor which is arranged in the first or second ground line, wherein the controller is designed in such a way that the microcontroller is able to detect, by measuring the current in the first and/or in the second ground line, whether a loss of the connection has occurred at one of the ground terminals.

In one development, the ground loss detection resistor is in the form of a printed circuit board resistor. This means that the shunt is not mounted on the printed circuit board as a component, but is realized with the aid of copper.

The object is also achieved by a brake system for a vehicle having a controller described above.

Further embodiments result from the subclaims and the description of exemplary embodiments on the basis of figures that follows.

### BRIEF DESCRIPTION OF THE DRAWINGS

In each case, schematically:

FIG. 1: shows a circuit for the detection of a ground loss (prior art); and

FIG. 2: shows a schematic representation of an embodiment of a controller.

### DETAILED DESCRIPTION

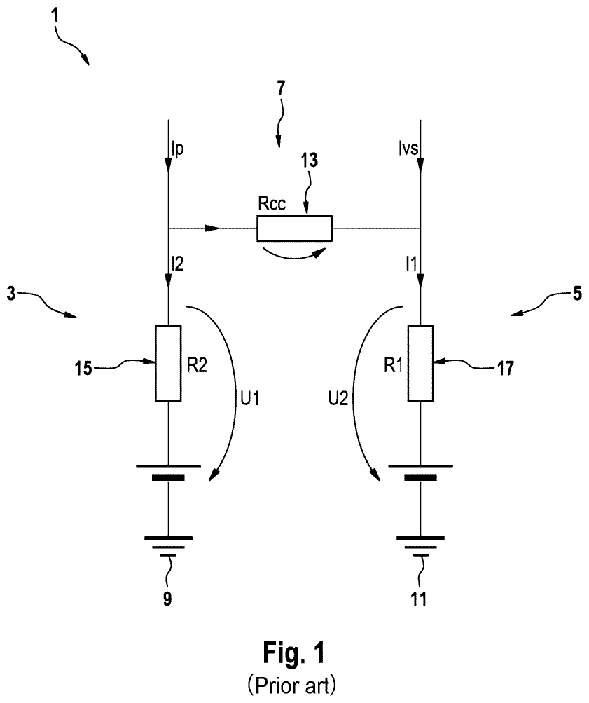

FIG. 1 is an illustration of a circuit 1 according to the prior art. The circuit comprises a first ground line 3, which is assigned to a first unit, and a second ground line 5, which is assigned to a second unit. The first ground line 3 and the second ground line 5 are connected to one another via a cross connection 7. The first ground line 3 is also connected to a first ground terminal 9 and the second ground line 5 is connected to a second ground terminal 11. A resistor 13 is arranged in the cross connection 7. Furthermore, in the first ground line 3, a first shunt 15 is arranged within the resistor R2 and, in the second ground line 5, a second shunt 17 is arranged within the resistor R1. Each resistor R1 and R2 comprises a series circuit composed of a shunt, contact resistor and line resistor.

Synchronization and a test pulse are required for this previous concept. The test pulse is a sufficiently large operating current. Overall, the concept is expensive and costs space on the printed circuit board due to two shunts.

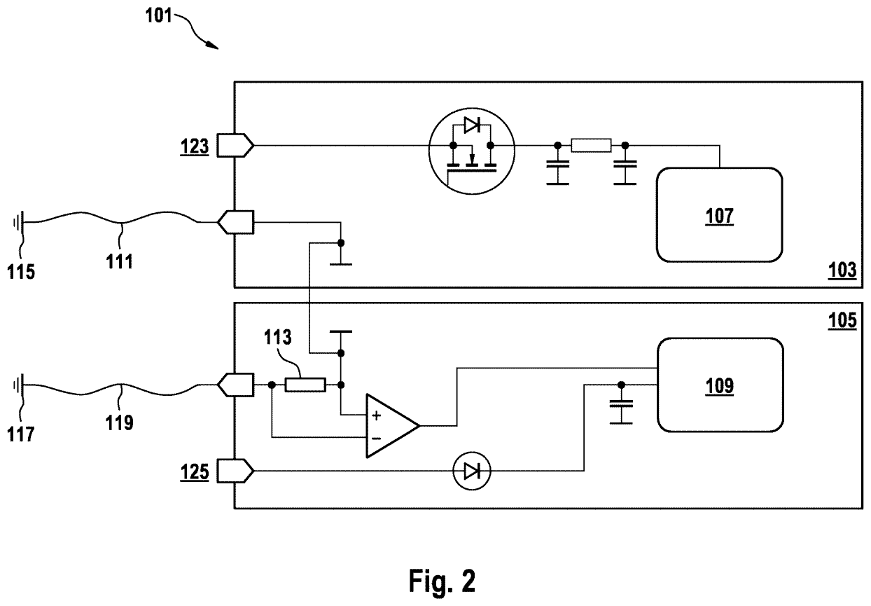

FIG. 2 shows an exemplary a schematic illustration of a controller 101 having a first unit 103 comprising a first printed circuit board and a second unit 105 comprising a second printed circuit board. The first unit 103 may be in the form of an actuator unit, for example. The second unit 105 may be in the form of a modulator unit, for example. A first microcontroller 107 is arranged in the first unit 103. A second microcontroller 109 is arranged in the second unit 105. A ground loss detection resistor 113, which is connected to a second ground terminal 117, is provided in a second ground line 119. The second ground terminal 117 is the connection to the body of the vehicle. A first ground terminal 115 is provided in the first unit 103 in a first ground line 111 and also represents a connection to the body of the vehicle. The first unit 103 and the second unit 105 are each connected to a power source 123 and 125. The power sources 123, 125 may include various individual sources here. The controller 101 may also have connectors, via which it is connected to the power sources 123, 125. The same applies to the connection to ground: The controller may also have connectors in this case, via which it is connected to ground (body of the vehicle).

When a ground, for example a ground line 111, 119, is interrupted, the current flow is forced to the respectively other ground path (ground line 111, 119). The “zero” current measurement of one path is thus transformed as “Max” current onto the other ground path. It is therefore possible to detect two limit values in one ground path. In other words, the interruption of the respective one or the other ground line can be detected using only a single ground loss detection resistor. In the first case, the current threshold value is undershot (zero current). The ground (ground terminal 115, 117) of one assembly (first unit 103, second unit 105) is interrupted. In the second case, the current threshold value is exceeded (MAX current). The ground of the other assembly is interrupted. This means that it is possible to dispense with the shunt in one assembly.

In other words, if one of the two ground lines, for example the first ground line, which has no shunt, has a defect, such as a tear, the current can no longer be measured there because current is no longer flowing or because there is no longer a shunt in this ground line. As a result of the tear, the total current now only flows via the remaining ground, that is to say the second ground line, with the shunt. The zero current in the defective ground line is thus transformed into a Max current in the line with the shunt. Consequently, the actually flowing current and not a potential increase of the substrate can also be measured. In this case, the circuit arrangement of the embodiment differs from the evaluation of the potential increase across the substrate resistance, if the test current flows off via the substrate. In this case, a quasi-digital signal is generated, which detects the ground interruption.

In contrast, in the circuit arrangement of the embodiment, the actually flowing current is measured in a quasi analog manner, and conclusions can be drawn about the functionality of the redundant ground terminal via the measured current.

In one development, consideration is also given to identifying asymmetries in the current distribution. It is thereby possible to predict a possible failure of a ground line.

The evaluation of whether a ground terminal 115, 117 is interrupted or is no longer available may be carried out by the second microcontroller 109. It is then possible to dispense with the first microcontroller 107. If several microcontrollers 107, 109 are present, the evaluation is always carried out by the microcontroller 107, 109 arranged in the unit 103, 105 in which the ground loss detection resistor 113 is also arranged. If the ground loss detection resistor 113 is housed, for example, in the second unit 105 (as shown in FIG. 2), then the evaluation is carried out by the microcontroller 109. As an alternative, the ground loss detection resistor 113 could also be housed in the first unit 103. In this case, the microcontroller 107 takes over the evaluation. If this is the case, the evaluation can be carried out with regard to hardware requirements and with regard to the individual process steps.

The current may be narrowly tolerated during the evaluation of the ground interruption detection. The current may therefore be in a window—that is to say between a minimum value and a maximum value—so that the GLD can be implemented with minimal effort in the evaluation. The level of the minimum required current during the evaluation depends on the offset error of the analog-to-digital converter in this evaluation procedure. The greater the offset error, the greater the current at the time of the evaluation. For small offset errors, continuous measurement is performed. To achieve a small offset error, this can be compensated for by software or an auto-zero function is integrated into the measurement chain as a function.

The shunt or ground loss detection resistor is in the form of a printed circuit board shunt for cost reasons. Therefore, the nominal resistance of the shunt depends on the tolerances of the printed circuit board layer thickness and the number of layers used of the printed circuit board used. Depending on the design of the shunt, the tolerance may be up to several 10%.

On the other hand, the resistance value of the shunt is influenced by the ambient temperature. To detect a ground interruption, the resistance value is therefore corrected in the controller using the known ambient temperature.

As another part of the implementation, the current is processed as a true RMS variable (root mean square). Therefore, the useful signal can be processed with maximum quantity. Furthermore, the implementation of further SW algorithms for hiding the evaluation for certain control functions of the brake controller, such as ABS, can therefore be omitted.

In the event that the application consists of two chipsets with different measurement accuracies, the ground loss detection can be transferred to the chipset with the best accuracy. Complex calculations, for example the current ratio, are no longer required. An implementation for two printed circuit board designs becomes simple compared to the ground loss detection calculated based on current ratios. Synchronized measurement of both currents is no longer required. For implementation, a unit for current measurement implemented in the chipset is used.

The current through the shunt is represented by a voltage drop and can be measured using an ADC (analog-to-digital converter). The digital signal is then converted into a current.

The individual shunt can be arranged either in the first unit 103 or in the second unit 105. A decision criterion for this may be which of the respective printed circuit boards in the first unit 103 or the second unit 105 has the better analog-to-digital converter for the detection of a ground loss. An ADC with a high accuracy at low currents may be selected here.

The measuring principle is as follows:

When both ground lines are in a fault-free state, the absolute ECU current is distributed almost equally across both ground lines (I1 and I2). The converted digital current value is then between a first threshold value and a second threshold value.

In the event that the ground line R1 is interrupted, the digital current value I1 falls below the first current threshold value. This makes it possible to detect a loss of ground on the ground line for R1.

In the event that the ground line R2 is interrupted, the digital current value I1 will exceed the second current threshold value. This makes it possible to detect a loss of ground in the ground line for R2.

The ground loss detection resistor 113 is arranged on one of the two printed circuit boards and inside the controller 101. The ground line 111, 119 is understood to be the (movable) cable connection between the attachment point on the vehicle body and the controller connector. The ground loss detection resistor 113 is arranged in series with the ground line 111, 119. Therefore, the sentence “the controller 101 comprises a single ground loss detection resistor 113 which is arranged in the first 111 or in the second ground line 119” is to be understood in this way.

A loss of the connection at one of the ground terminals 115, 117 is, for example, a tear in the ground line or else a faulty connection at the connector of the controller.

1. A method for detecting a loss of ground connection in a controller for a vehicle comprising:
ascertaining current in at least one of a first ground line which connects a first unit to a first ground terminal and a second ground line which connects a second unit to a second ground terminal and having a single ground loss detection resistor in one of the first and the second ground lines; and
evaluating the measured current with a microcontroller of at least one of the first unit and the second unit to determine whether a loss of the connection has occurred at one of the first and second ground terminals.

2. The method as claimed in claim 1, wherein the evaluating microcontroller and the ground loss detection resistor are arranged in the second unit.

3. The method as claimed in claim 1, wherein the first unit comprises a first printed circuit board and the second unit comprises a second printed circuit board, wherein the first printed circuit board is connected to the first ground terminal via the first ground line and the second printed circuit board is connected to the second ground terminal via the second ground line.

4. The method as claimed in claim 1, further comprising detecting a ground interruption under at least one of normal operating conditions and purely using operating current.

5. The method as claimed in claim 1, wherein the actually flowing current is measured.

6. The method as claimed in claim 1, further comprising:
identifying a loss of connection via the second ground line when the current falls below a first current threshold value; and
identifying a loss of connection via the first ground line when the current exceeds a second current threshold value.

7. The method as claimed in claim 1, selecting a level of minimum required current for the evaluation depending on the offset error of the analog-to-digital converter.

8. The method as claimed in claim 7, wherein the minimum current is selected to be greater, the greater the offset error is.

9. The method as claimed claim 1, further comprising correcting the resistance value of the ground loss detection resistor by the ambient temperature.

10. The method as claimed in claim 1, further comprising correcting the nominal resistance of the ground loss detection resistor by the tolerances of the printed circuit board.

11. A controller for a vehicle comprising:
a first unit;
a second unit;
a microcontroller of at least one of the first unit and the second units;
a first ground terminal connected to the first unit by a first ground line;
a second ground terminal connected to the second unit by a second ground line;
a single ground loss detection resistor arranged in one of the first ground line and the second ground line, wherein the microcontroller is able to detect whether a loss of the connection has occurred at one of the ground terminals by measuring the current in one of the first and the second ground lines.

12. The controller as claimed in claim 11, wherein the ground loss detection resistor is a printed circuit board resistor.

13. The controller as claimed in claim 11, wherein the controller is for a brake system of the vehicle.

14. The method of claim 1, wherein the loss of detection is for a redundant ground connection.
